(19) United States
(12) Patent Application Publication
(10) Pub. No.: US 2008/0122089 A1
(43) Pub. Date: May 29, 2008

(54) INTERCONNECT STRUCTURE WITH LINE RESISTANCE DISPERSION

(75) Inventor: Tadashi Iijima, Kawasaki (JP)

Correspondence Address: BANNER & WITCOFF, LTD.;ATTORNEYS FOR CLIENT NO. 000449, 001701, 1100 13th STREET, N.W., SUITE 1200, WASHINGTON, DC, 20005-4051, US

(73) Assignee: TOSHIBA AMERICA ELECTRONIC COMPONENTS, INC., Irvine, CA (US)

(21) Appl. No.: 11/557,674

(22) Filed: Nov. 8, 2006

(51) Int. Cl. H01L 23/528

(52) U.S. Cl. 257/741; 257/775; 257/E23.152

(57) ABSTRACT

A semiconductor device is provided. The semiconductor device includes a region of closely packed lines and a region including an isolated line, separated by a region of carbon doped silicon oxide. As the surface of the semiconductor device is etched, the etching rate varies depending on the material being etched. Accordingly, the cross-sectional area of the isolated line must be adjusted to compensate for the slowed etching process in that region. The close packed lines may have a height, a, and a width, b thus having a cross-sectional area of a*b. However, the isolated line may have a height D*a, and a width, E*b, where D*E=1. Singular or multiple etching processes may used and the line widths adjusted accordingly.

### BACKGROUND

A conventional semiconductor device includes two general types of lines: those in closely spaced groups and those in groups that are effectively isolated from each other. In some arrangements, the lines are separated by carbon doped silicon oxide (SiCOH). During the manufacturing process, material is generally deposited on the semiconductor device and an etching process is performed to planarize the topography of the semiconductor device surface.

The rate at which this etching process is performed can vary depending on material type. This often results in a faster etch rate in the region of close packed lines and a slower etch rate in the SiCOH and/or isolated line regions. The difference in etch rates can result in close packed lines having a different resistance than the isolated line because of the unaccounted for greater height of the isolated line. This can cause performance issues, such as race conditions, unexpected voltage levels, etc.

### SUMMARY

This summary is provided to introduce a selection of concepts in a simplified form that are further described below in the Detailed Description. This summary is not intended to identify key features or essential features of the claimed subject matter.

There is a need to provide a semiconductor device manufacturing process that provides generally uniform resistance for the lines between various regions. In order to provide this uniform resistance, the cross-sectional area of each line should be generally uniform once the etching process is complete. In order to provide this generally uniform cross-sectional area, the width of the isolated line may be adjusted to accommodate for its generally greater height. This provides a generally uniform cross-sectional area for the close packed and isolated lines, thereby providing a generally uniform resistance for each of those lines.

These and other aspects of the disclosure will be apparent upon consideration of the following detailed description of illustrative embodiments.

### BRIEF DESCRIPTION OF THE DRAWINGS

A more complete understanding of the present invention and the potential advantages thereof may be acquired by referring to the following description of illustrative embodiments in consideration of the accompanying drawings, in which like reference numbers indicate like features, and wherein:

FIG. 1 is a cross-sectional view of a desired semiconductor device showing regions of close packed and isolated lines.

FIG. 2 is a cross-sectional view of one arrangement of a conventional semiconductor device.

FIG. 3 is a graph illustrating the results of the etching process in a conventional arrangement.

FIG. 4A is a cross-sectional view of a semiconductor device according to one arrangement in which the resistances of the close packed and isolated lines are equal.

FIG. 4B is a graph showing capacitance variations as dimensions of the lines change in accordance with aspects of the invention.

FIG. 5 is a cross-sectional view of a semiconductor device according to another arrangement in which the resistances of the close packed and isolated lines are equal in accordance with aspects of the present invention.

FIGS. 6A and 6B are graphs illustrating actual and desired line resistance as it varies by wafer position according to aspects of the present invention

FIGS. 7A and 7B show etch rates for CMP and RIE in accordance with aspects of the present invention.

FIG. 8 shows combined etch rates for CMP and RIE in accordance with aspects of the present invention.

### DETAILED DESCRIPTION

The various aspects summarized previously may be embodied in various forms. The following description shows by way of illustration of various embodiments and configurations in which the aspects may be practiced. It is understood that the described embodiments are merely examples, and that other embodiments may be utilized and structural and functional modifications may be made, without departing from the scope of the present disclosure.

It is noted that various connections are set forth between elements in the following description. It is noted that these connections in general and, unless specified otherwise, may be direct or indirect and that this specification is not intended to be limiting in this respect.

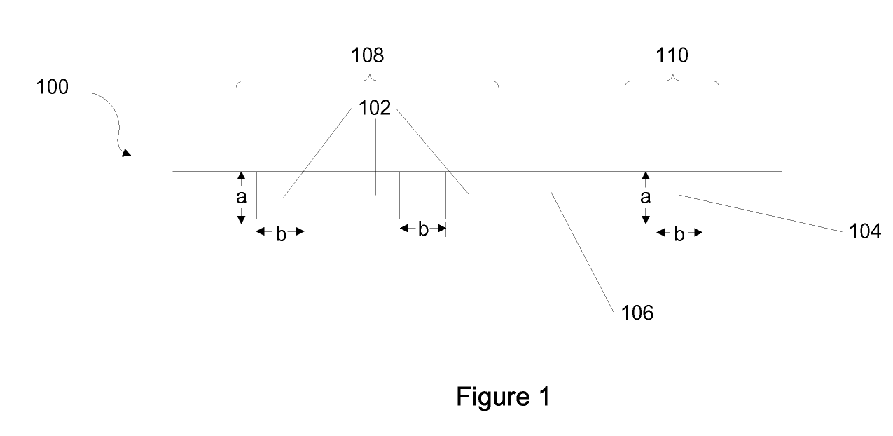

FIG. 1 illustrates a conventional semiconductor device 100 exhibiting desirable characteristics. The device 100 includes a region 108 of closely packed lines 102. In addition, the semiconductor device 100 includes a region 110 including an isolated line 104. Both the closely packed lines 102 and the isolated line 104 may be formed of copper, or other metal or metalization. Although only one isolated line 104 is shown, a plurality of isolated lines may be formed on the semiconductor device. The lines 102, 104 may be surrounded by a region of carbon doped silicon oxide (SiCOH) 106, or other insulation. In one exemplary arrangement, the SiCOH layer is between 100 nm and 4000 nm, depending on line pitch for the various metal layers. Also, line pitch may be between 160 nm (where the line/spaces are approximately 80 nm/80 nm) and 100 μm (where the line/spaces are approximately 50 μm /50 μm).

During manufacture of the semiconductor device 100, an etching process is performed on the surface of the device to even out and/or planarize the topography of the surface. The etching may be done using any suitable process, such as chemical mechanical polishing, damascene processing or reactive ion etching, for instance.

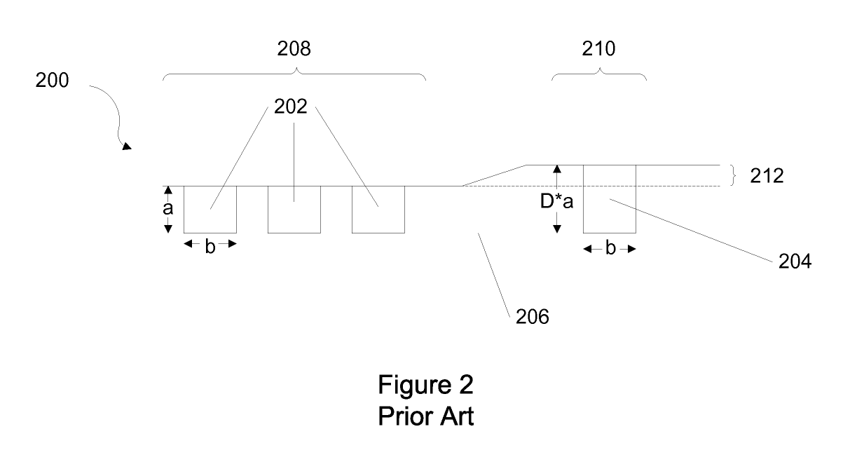

During this etching process, a portion of each of the close packed 102 and isolated lines 104 is removed. Because metal generally etches at a faster rate than insulator material, the etching process proceeds at a faster rate in the close packed region 108, than in the isolated region 110. For example, if chemical mechanical polishing (CMP) is used, the polish time for copper region may be 230 seconds, while the smaller liner region polish time is 120 seconds, yielding a total polish time of 350 seconds. Also, if reactive ion etching (RIE) is used, the total polish time may be 600 seconds with actual line etching taking 70 seconds. This increased etch rate is due to a greater portion of the surface area being metal in the close packed region 108 than in the isolated region 110. The resulting semiconductor device is illustrated in FIG. 2 and will be discussed further below.

FIG. 1 further illustrates a desired semiconductor device 100 in which the resistance of the closely packed lines 102 is equal to the resistance of the isolated line 104. For example, each of the closely packed lines 102, as well as the isolated line 104, has a height, “a,” and a width, “b.” The cross-sectional area A₁ of each line is represented by:

A₁=a*b

In addition, each of the lines 102 in the close packed region 108 are spaced equally from each other. For example, the lines 102 are generally spaced a distance equal to their width, “b” to allow for the closest possible arrangement without any detrimental effects.

The uniform cross-sectional area of the closely packed lines 102 and the isolated line 104 provided in FIG. 1 provides a generally uniform resistance for each line. The equal resistance is a desirable quality to provide predictable behavior and aids in reducing power consumption and unexpected voltage levels. However, this arrangement can be difficult to achieve in real world conditions.

Due to the difference in the etch rates in the various regions 108, 110, the resistance of the lines 102, 104 may differ. For instance, the slowing etching in the isolated line region 110 may cause the isolated line 104 to be of a greater height, as shown in the semiconductor device 200 of FIG. 2, thereby having a different cross sectional area than the lines in the close packed region. For example, the closely packed lines 202 of FIG. 2 each have a height “a,” and a width “b.” The cross-sectional area, A_{Close} of each of those lines is represented by:

A_{Close}=a*b

However, the isolated line 204 has a height, “D*a” and a width “b.” The cross-sectional area, A_{Isolated} for this line is represented by:

A_{Isolated}=(D*a)*b

The increased cross-sectional area caused by the increased height of the line 204 decreases the resistance by a factor of D. The increase in height, D, is because of the reduced etching of region 210. The reduced etching rate is embodied by non-etched height 212. The non-etched height 212 is due to the differing etch rates based on the percent coverage area of the metal lines compared to that of the insulator. This difference in resistance may lead to unpredictable behavior in addition to power issues and line voltage value discrepancies.

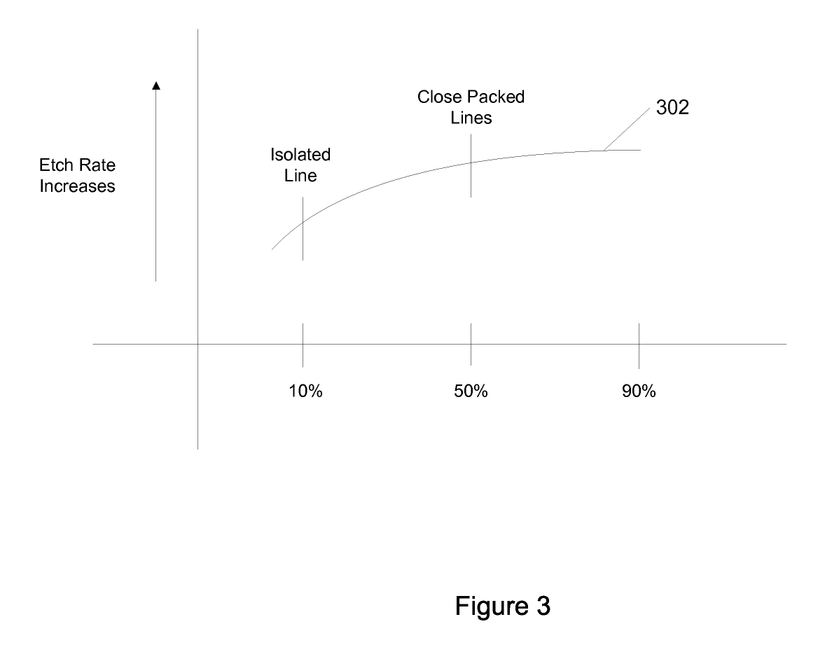

In order to produce a semiconductor device with predictable behavior and reasonable power consumption, the cross-sectional area of the closely packed lines and the isolated line should be approximately equal. For instance, the cross-sectional areas may have less than 5% difference or, preferably, less than 1% difference. The graph in FIG. 3 illustrates various etch rates based on different coverage areas of the metal. As shown by line 302, as the percentage of metal surface area increases, the etch rate also increases. For instance, approximately 10% of the isolated line region surface area may be metal, causing a slower etch rate than the close packed region in which approximately 50% of the surface area may be metal. Accordingly, increased etching will occur in the close packed region causing the cross-sectional area of the close packed lines to be smaller than the isolated line. Since equalizing the etch rate for the different materials is not feasible, the cross-sectional area of one or more of the lines must be adjusted to maintain an equal resistance for all lines. In addition, the mask may be remade to compensate for the difference in calculations when using chemical mechanical polishing or reactive ion etching, or any combination of etching processes.

In one illustrative arrangement, a similar process is used to manufacture the semiconductor device as with a conventional device. However, the isolated line may have a narrower width than the close packed lines. For example, the width of the isolated line may be “E*b”, where E is a number less than 1. Accordingly, the height of the isolated line is “D*a,” as above. In order to maintain the same cross-sectional area as the close packed lines, D*E=1. For example:

$$a * b = ( D * a ) * ( E * b )$$

$$1 = D * E$$

$$D = \frac{1}{E}$$

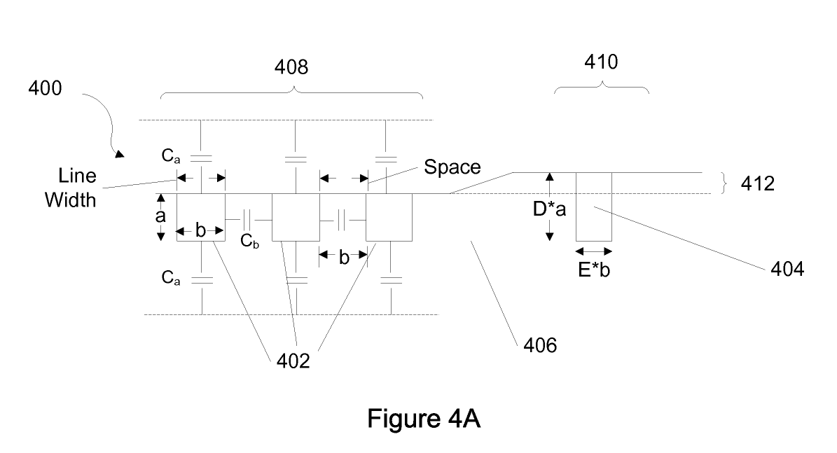

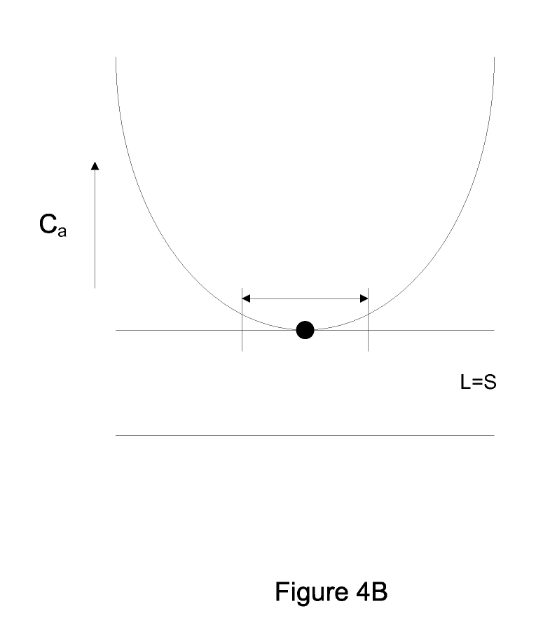

FIG. 4A illustrates a semiconductor device 400 according to this arrangement. The semiconductor device 400 includes a plurality of closely packed lines 402, an isolated line 404 and a SiCOH region 406. The close packed lines 402 have a height “a,” and a width “b.” Accordingly, the cross-sectional area of the closely packed lines 402 is represented by:

A_{Close}=a*b

The spacing of the lines in the closely packed region 408 may be determined by the following: If it is determined that the length of the line (L) and the length of the space (S) are equal then the interconnect capacitance is minimized. If the length of the line is adjusted by 3.6% then the interconnect capacitance may increase up to 10%. This is shown in FIG. 4B where capacitance has been minimized. The bracket refers to an approximate 3.6% swing in line size and corresponding 10% swing in line capacitance. While equal line and space pitch may provide some benefits, one may also set the tolerance to 10% or more for easier processing. So, for example, if the line/space width is 100 nm/100 nm, then a 10% capacitance tolerance would be 7.2 nm. The isolated line 404 has a height, “D*a,” and a width “E*b.” The width of the isolated line 404 has been compensated for the extra height 412 of isolated region 410. Accordingly the cross-sectional area of the isolated line 404 is represented by:

A_{Isolated}=(D*a)*(E*b)

In order to make the cross-sectional area of the closely packed 402 and isolated lines 404, as well as the resistance of the lines, approximately equal, D*E should equal 1. For example, if D=1.2, E=0.83. Additionally, if D=1.1, E=0.9. Also, if D=1.25, E=0.8. Because the thickness of a line is difficult to control, a mask may be modified from an original line width E=1 to E=0.83, thereby accounting for the increase in depth D by decreasing the line width E.

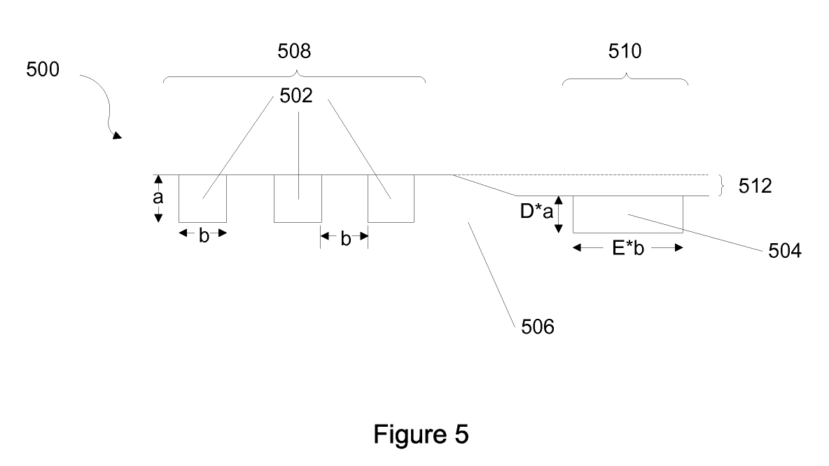

In yet another aspect of the invention, D may be less than 1, while E is greater than 1. FIG. 5 illustrates a semiconductor device 500 according to this arrangement. In the semiconductor device 500, the etch rate is slower in the isolated region 510 and faster in the close packed region 508. The different etch rates may be due to different insulators resulting in different etch rates.

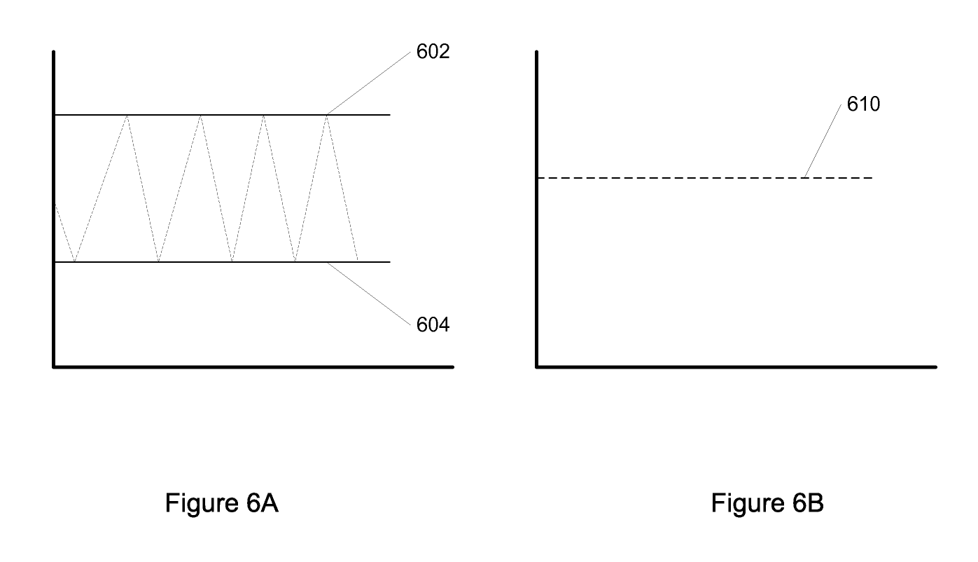

FIG. 6A is a graph illustrating one aspect of how the L/S ratio can affect line resistance. As shown, variations in line resistance can occur based on the position of the line on the wafer based on how actual etching varies the line height (and resistance) of the various lines. For instance, a line can have greater or less resistance depending on whether it is located in the closely packed region or isolated region. As seen in FIG. 6A, line resistance fluctuates between a best case 604 and a worst case 602 depending on the position of the line. FIG. 6B illustrates the desired line resistance according to one or more aspects of the invention. Line 610 is illustrative of a generally constant line resistance regardless of the position of the line on the wafer. Having a generally constant line resistance may make chip design easier.

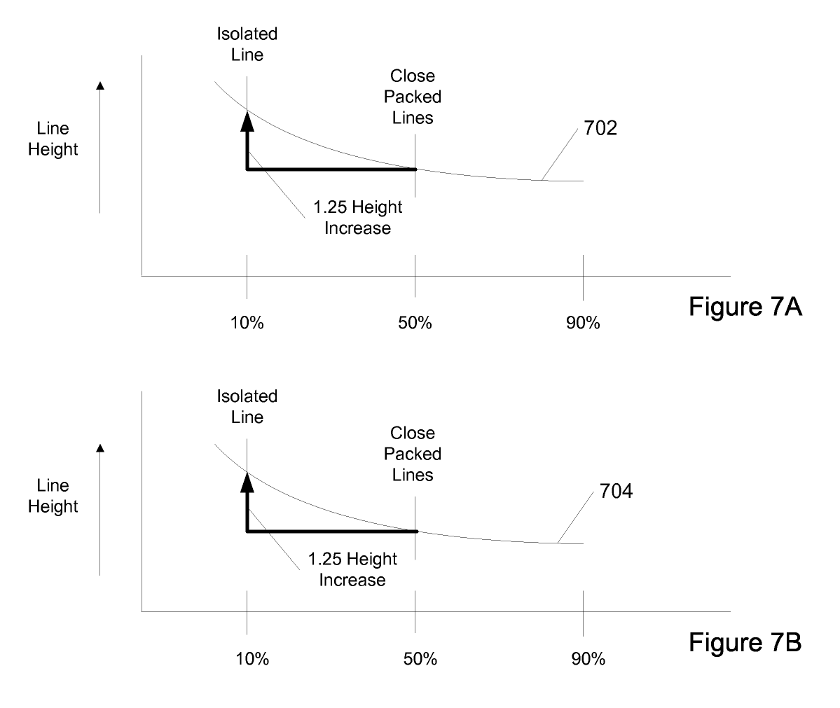

Different types of etching processes may be used. For instance, FIGS. 7A and 7B show the link height increase of the etching of lines in isolated regions compared to those lines in closely packed regions. FIG. 7A shows a first type of etching, for example, CMP as varying along slope 702. Here, the line height increase is 1.25 in the isolated line region when using CMP. Here, a designer would then adjust the line width E would then be adjusted to be 0.8 to compensate for the increased height. This may mean that the mask is adjusted to compensate for this new value of E.

FIG. 7B shows the etching of lines using a different type of etching process, for example, RIE as varying along slope 704. For simplicity, the same increase in line height is shown for the purpose of illustration. Of course, the line height increase may vary for different types of etchants, different types of conditions, materials being etched, and the like.

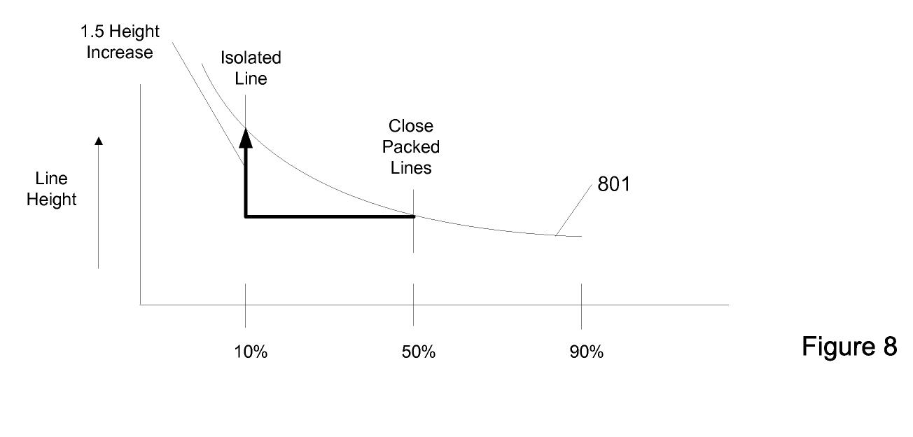

FIG. 8 shows the combination of the etching processes of FIGS. 7A and 7B. In FIG. 8, both etching processes have been used. Here, the designer determines the line height increase for the isolated lines for the combination of etching processes and adjusts the mask pattern for the lines in the isolated line regions to compensate for the increase. For example, if a line height due to CMP increase was 1.25 and the line height increase due to RIE was 1.25, then the total line height increase may be 1.5625(=1.25×1.25). Accordingly, the designer may then adjust the mask for the lines in the isolated line region to compensate for the 1.5625 line height increase. Accordingly, the line width may be reduced to 0.64(=1/1.5625), for instance. It is appreciated that different etching process, ratios, materials, etc. will vary the line height increase (or decrease) to varying degrees. Using the process described above, a designer may then vary the line width accordingly to compensate for the varying line heights.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims. Numerous other embodiments, modifications and variations within the scope and spirit of the appended claims will occur to persons of ordinary skill in the art from a review of this disclosure.

What is claimed is:

1. A semiconductor device, comprising:
a plurality of close packed lines, the close packed lines having a width, b;
an isolated line, the isolated line having a width E*b; and
wherein the plurality of close packed lines and the isolated line are etched to provide close packed lines having a height, a and isolated line having a height D*a;
where
$$D \approx \frac{1}{E} .$$

2. The semiconductor device of claim 1, wherein D=1.2 and E=0.83.

3. The semiconductor device of claim 1, wherein D is 1.1 and E is 0.91.

4. The semiconductor device of claim 1, wherein D is 1.25 and E is 0.80.

5. The semiconductor device of claim 1, wherein the etching process includes a chemical-mechanical polishing process.

6. The semiconductor device of claim 1, wherein the etching process includes a reactive ion etching process.

7. The semiconductor device of claim 1, wherein the etching process includes a damascene process.

8. The semiconductor device of claim 1, wherein the relationship between D and E is linear.

9. The semiconductor device of claim 1, wherein the close packed lines and the isolated line are formed of copper.

10. The semiconductor device of claim 1, further including a region of carbon doped silicon oxide between the plurality of close packed lines and the isolated line.

11. A semiconductor device, comprising:
a first plurality of lines, each of the lines having a width, b;
a second plurality of lines, each of the lines having a width, E*b,;
wherein the first plurality of lines is etched to a height, a and the second plurality of lines is etched to a height, D*a; and
a substrate region connecting the first plurality of lines with the second plurality of lines.

12. The semiconductor device of claim 11, wherein D=1.1 and E=0.91.

13. The semiconductor device of claim 11, wherein D=1.2 and E=0.83.

14. The semiconductor device of claim 11, wherein D=1.25 and E=0.80.

15. The semiconductor device of claim 11, wherein the etching process includes a chemical mechanical polishing process.

16. The semiconductor device of claim 11, wherein the etching process includes a reactive ion etching process.

17. The semiconductor device of claim 11, wherein the etching process includes a damascene process.

18. The semiconductor device of claim 11, wherein E is a number greater than 1 and D is a number less than 1 and D*E≈1.

19. The semiconductor device of claim 11, wherein the first plurality of lines and the second plurality of lines are formed of copper.

20. The semiconductor device of claim 11, wherein the substrate region is formed of carbon doped silicon oxide.
